(19) United States
(12) Patent Application Publication
(10) Pub. No.: US 2024/0379730 A1
(43) Pub. Date: Nov. 14, 2024

(54) LIGHT EMITTING DEVICE

(71) Applicant: Japan Display Inc., Tokyo (JP)

(72) Inventor: Masumi NISHIMURA, Tokyo (JP)

(73) Assignee: Japan Display Inc., Tokyo (JP)

(21) Appl. No.: 18/783,616

(22) Filed: Jul. 25, 2024

Related U.S. Application Data
(63) Continuation of application No. PCT/JP2022/042981, filed on Nov. 21, 2022.

(30) Foreign Application Priority Data
Jan. 28, 2022 (JP) 2022-011706

(51) Int. Cl. H01L 27/15

(52) U.S. Cl. CPC H01L 27/156

(57) ABSTRACT

A light emitting device includes a plurality of pixels arranged in a matrix in a first direction and in a second direction orthogonal to the first direction, over a substrate. Each of the plurality of pixels arranged in a matrix includes a conductive alignment layer over the substrate, a semiconductor layer including gallium nitride over the conductive alignment layer, a light emitting layer in an island shape over the semiconductor layer, and an electrode layer over the light emitting layer. A side surface of the light emitting layer is covered with an insulating layer. A reflective layer facing the side surface of the light emitting layer is provided over the insulating layer.

### CROSS-REFERENCE TO RELATED APPLICATIONS

This application is a Continuation of International Patent Application No. PCT/JP2022/042981, filed on Nov. 21, 2022, which claims the benefit of priority to Japanese Patent Application No. 2022-011706, filed on Jan. 28, 2022, the entire contents of which are incorporated herein by reference.

### FIELD

An embodiment of the present invention relates to a light emitting device including gallium nitride. Further, an embodiment of the present invention relates to a light emitting device formation substrate on which a plurality of light emitting devices including gallium nitride are formed.

### BACKGROUND

Gallium nitride (GaN) is characterized as a direct bandgap semiconductor with a large bandgap. This feature of gallium nitride is utilized and a light emitting diode (LED) using a gallium nitride film has already been in practical use. The gallium nitride film for the LED is generally formed on a sapphire substrate at a high temperature of 800 degrees to 1000 degrees using MOCVD (Metal Organic Chemical Vapor Deposition) or HVPE (Hydride Vapor Phase Epitaxy).

In recent years, the development of a so-called micro LED display device or a mini-LED display device in which minute micro LEDs are mounted in pixels on a circuit substrate is proceeding as a next-generation display device. The micro LED display device or the mini-LED display device has high efficiency, high brightness and high reliability. Such a micro LED display device or a mini-LED display device is manufactured by transferring a LED chip to a backplane on which a transistor using an oxide semiconductor or low-temperature polysilicon is formed (for example, see U.S. Pat. No. 8,791,474).

### SUMMARY

A light emitting device according to an embodiment of the present invention includes a plurality of pixels arranged in a matrix in a first direction and in a second direction orthogonal to the first direction, over a substrate. Each of the plurality of pixels arranged in a matrix includes a conductive alignment layer over the substrate, a semiconductor layer including gallium nitride over the conductive alignment layer, a light emitting layer in an island shape over the semiconductor layer, and an electrode layer over the light emitting layer. A side surface of the light emitting layer is covered with an insulating layer. A reflective layer facing the side surface of the light emitting layer is provided over the insulating layer.

A light emitting device according to an embodiment of the present invention includes a plurality of pixels arranged in a matrix in a first direction and in a second direction orthogonal to the first direction, over a substrate. Each of the plurality of pixels arranged in a matrix includes an insulating alignment layer over the substrate, a semiconductor layer comprising gallium nitride over the insulating alignment layer, a light emitting layer in an island shape over the semiconductor layer, an electrode layer over the light emitting layer, an insulating layer covering a side surface of the light emitting layer, and a reflective layer facing the side surface of the light emitting layer, over the insulating layer. The reflective layer is in contact with the semiconductive layer.

### BRIEF DESCRIPTION OF DRAWINGS

FIG. 1 is a schematic diagram showing a configuration of a light emitting device according to an embodiment of the present invention.

FIG. 2A is a schematic cross-sectional view showing a configuration of a light emitting device according to an embodiment of the present invention.

FIG. 2B is a schematic cross-sectional view showing a configuration of a light emitting device according to an embodiment of the present invention.

FIG. 3A is a schematic cross-sectional view showing a configuration of a light emitting device according to an embodiment of the present invention.

FIG. 3B is a schematic cross-sectional view showing a configuration of a light emitting device according to an embodiment of the present invention.

FIG. 4A is a schematic cross-sectional view showing a configuration of a light emitting device according to an embodiment of the present invention.

FIG. 4B is a schematic cross-sectional view showing a configuration of a light emitting device according to an embodiment of the present invention.

FIG. 5A is a schematic cross-sectional view showing a configuration of a light emitting device according to an embodiment of the present invention.

FIG. 5B is a schematic cross-sectional view showing a configuration of a light emitting device according to an embodiment of the present invention.

FIG. 6A is a schematic cross-sectional view showing a configuration of a light emitting device according to an embodiment of the present invention.

FIG. 6B is a schematic cross-sectional view showing a configuration of a light emitting device according to an embodiment of the present invention.

FIG. 7A is a schematic cross-sectional view showing a method for manufacturing a light emitting device according to an embodiment of the present invention.

FIG. 7B is a schematic cross-sectional view showing a method for manufacturing a light emitting device according to an embodiment of the present invention.

FIG. 7C is a schematic cross-sectional view showing a method for manufacturing a light emitting device according to an embodiment of the present invention.

FIG. 7D is a schematic cross-sectional view showing a method for manufacturing a light emitting device according to an embodiment of the present invention.

FIG. 7E is a schematic cross-sectional view showing a method for manufacturing a light emitting device according to an embodiment of the present invention.

FIG. 8A is a schematic cross-sectional view showing a configuration of a light emitting device according to an embodiment of the present invention.

FIG. 8B is a schematic cross-sectional view showing a configuration of a light emitting device according to an embodiment of the present invention.

FIG. 9A is a schematic cross-sectional view showing a configuration of a light emitting device according to an embodiment of the present invention.

FIG. 9B is a schematic cross-sectional view showing a configuration of a light emitting device according to an embodiment of the present invention.

FIG. 10A is a schematic cross-sectional view showing a configuration of a light emitting device according to an embodiment of the present invention.

FIG. 10B is a schematic cross-sectional view showing a configuration of a light emitting device according to an embodiment of the present invention.

FIG. 11A is a schematic cross-sectional view showing a method for manufacturing a light emitting device according to an embodiment of the present invention.

FIG. 11B is a schematic cross-sectional view showing a method for manufacturing a light emitting device according to an embodiment of the present invention.

FIG. 11C is a schematic cross-sectional view showing a method for manufacturing a light emitting device according to an embodiment of the present invention.

FIG. 11D is a schematic cross-sectional view showing a method for manufacturing a light emitting device according to an embodiment of the present invention.

FIG. 11E is a schematic cross-sectional view showing a method for manufacturing a light emitting device according to an embodiment of the present invention.

FIG. 12 is a schematic cross-sectional view showing a configuration of a light emitting device according to an embodiment of the present invention.

FIG. 13 is a schematic diagram showing a configuration of a light emitting device formation substrate according to an embodiment of the present invention.

### DESCRIPTION OF EMBODIMENTS

The method for manufacturing a micro LED display device by transferring LED chips has a high manufacturing cost, and it is difficult to manufacture the micro LED display device at low cost. On the other hand, if LEDs can be formed on a large-area substrate such as an amorphous glass substrate, the manufacturing cost can be reduced. However, as described above, since a gallium nitride film is formed on a sapphire substrate at a high temperature, it is difficult to form a gallium nitride film directly on an amorphous glass substrate.

Further, in an LED using gallium nitride, light is emitted not only from the lower surface of the LED but also from the side surface of the LED. Therefore, if the light emitted from the side surface of the LED can be utilized in a light emitting device, the light emission efficiency in the lower surface direction of the light emitting device can be improved. Moreover, the power consumption of the light emitting device can be reduced.

In view of the above problems, an embodiment of the present invention can provide a light emitting device that includes a semiconductor containing gallium nitride formed on a large-area substrate such as an amorphous glass substrate and has high light extraction efficiency in the lower surface direction. Further, an embodiment of the present invention can provide a light emitting device formation substrate on which a plurality of light emitting devices that include a semiconductor layer containing gallium nitride and have high light extraction efficiency in the lower surface direction are formed.

In the following description, each of the embodiments of the present invention are described with reference to the drawings. Each of the embodiments is merely an example, and a person skilled in the art could easily conceive of the invention by appropriately changing the embodiment while maintaining the gist of the invention, and such changes are naturally included in the scope of the invention. For the sake of clarity of the description, the drawings may be schematically represented with respect to the widths, thicknesses, shapes, and the like of the respective portions in comparison with actual embodiments. However, the illustrated shapes are merely examples and are not intended to limit the interpretation of the present invention.

In the present specification, the expressions “a includes A, B or C”, “a includes any of A, B and C”, and “a includes one selected from the group consisting of A, B and C” do not exclude the case where a includes a plurality of combinations of A to C unless otherwise specified. Further, these expressions do not exclude the case where a includes other elements.

In the present specification, although the phrase “above” or “above direction” or “below” or “below direction” is used for convenience of explanation, in principle, the direction from a substrate toward a structure is referred to as “above” or “above direction” with reference to a substrate in which the structure is formed. Conversely, the direction from the structure to the substrate is referred to as “below” or “below direction”. Therefore, in the expression of a structure over a substrate, one surface of the structure in the direction facing the substrate is the bottom surface of the structure and the other surface is the upper surface of the structure. In addition, the expression of a structure over a substrate only explains the vertical relationship between the substrate and the structure, and another member may be placed between the substrate and the structure. Furthermore, the terms “above” or “above direction” or “below” or “below direction” mean the order of stacked layers in the structure in which a plurality of layers are stacked, and may not be related to the position in which layers overlap in a plan view.

In the specification, terms such as “first”, “second”, or “third” attached to each configuration are convenient terms used to distinguish each configuration, and have no further meaning unless otherwise explained.

In the specification and the drawings, the same reference numerals may be used when multiple configurations are identical or similar in general, and reference numerals with an upper case letter of the alphabet may be used when the multiple configurations are distinguished. Further, reference numerals with a hyphen and a lower case letter may be used when specific portions of one configuration are distinguished.

In the specification, although gallium nitride is described as an example in order to facilitate understanding of the invention, each embodiment is not limited to gallium nitride. In each embodiment, a nitride semiconductor such as gallium nitride or aluminum gallium nitride can be applied.

The following embodiments can be combined with each other as long as there is no technical contradiction.

### First Embodiment

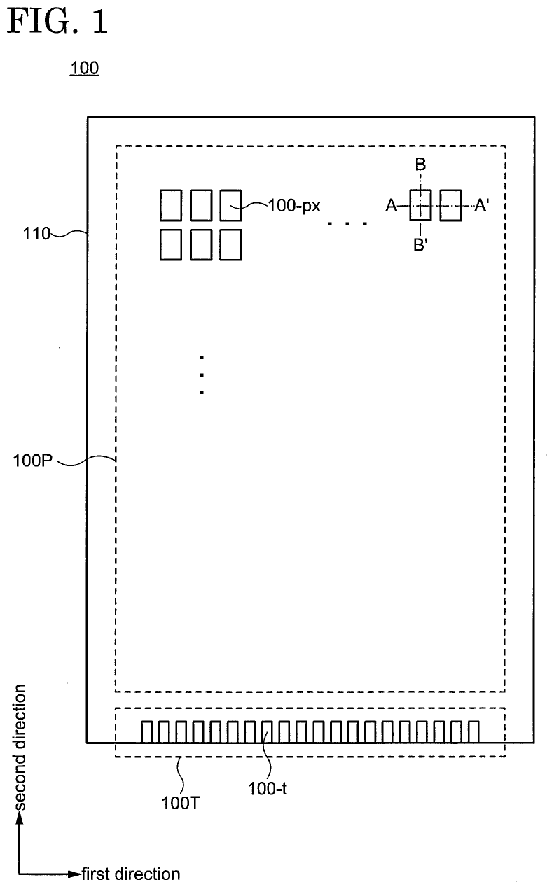

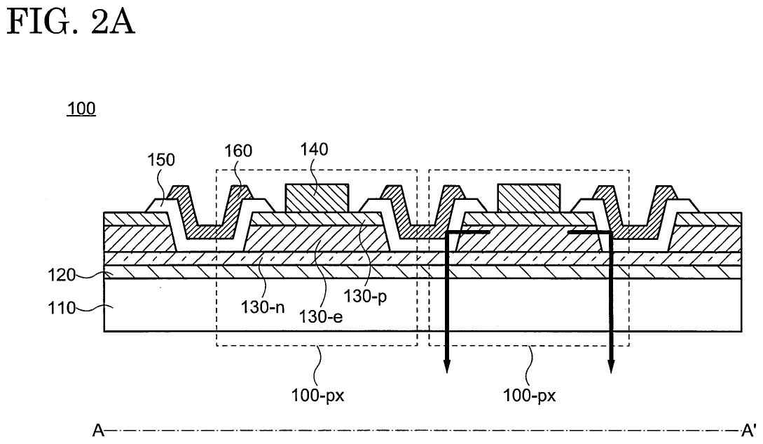

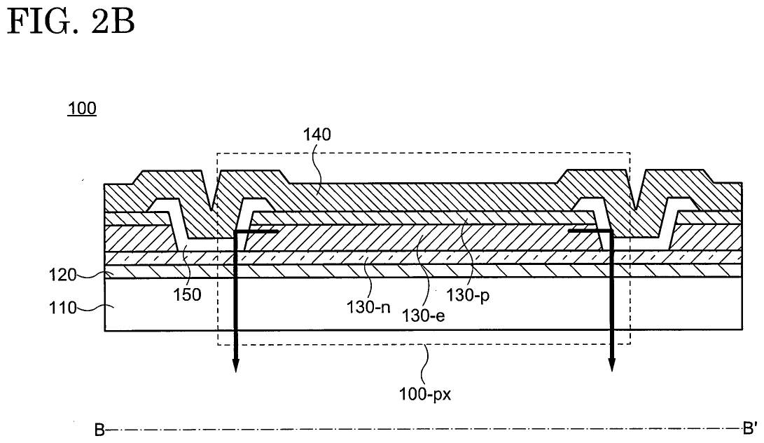

A configuration of a light emitting device 100 according to an embodiment of the present invention is described with reference to FIGS. 1 to 2B.

FIG. 1 is a schematic diagram showing a configuration of the light emitting device 100 according to an embodiment of the present invention. In the light emitting device 100, a pixel section 100P and a terminal section 100T are formed on a substrate 110. The pixel portion 100P is formed in the center of the substrate 110, and the terminal portion 100T is formed at an end of the substrate 110. The pixel portion 100P includes a plurality of pixels 100-px arranged in a matrix in a first direction and a second direction orthogonal to (intersecting) the first direction. Although details are described later, a light emitting diode (LED) is formed in each of the plurality of pixels 100-px. The terminal portion 100T includes a plurality of terminals 100-t. A power supply line is connected to each of the plurality of terminals 100-t, and a voltage can be applied (a current can be supplied) to the LED in the pixel 100-px. In addition, although details are not shown, a transistor can be provided in the pixel 100-px, and the light emission of the LED can be controlled by the transistor.

FIGS. 2A and 2B are schematic cross-sectional views showing a configuration of the light emitting device 100 according to an embodiment of the present invention. Specifically, FIG. 2A is a cross-sectional view of the pixel 100-px cut along the first direction (line A-A′) shown in FIG. 1, and FIG. 2B is a cross-sectional view of the pixel 100-px cut along the second direction (line B-B′) shown in FIG. 1. As shown in FIGS. 2A and 2B, the light emitting device 100 includes a substrate 110, a conductive alignment layer 120, an n-type semiconductor layer 130-n, a light emitting layer 130-e, a p-type semiconductor layer 130-p, an electrode layer 140, an insulating layer 150, and a reflective layer 160.

The conductive alignment layer 120 is provided on the substrate 110. The conductive alignment layer 120 is provided commonly in a plurality of pixels 100-px arranged in a matrix.

The n-type semiconductor layer 130-n, the light emitting layer 130-e, and the p-type semiconductor layer 130-p are sequentially provided on the conductive alignment layer 120. The n-type semiconductor layer 130-n is provided commonly in the plurality of pixels 100-px arranged in a matrix. Each of the light emitting layer 130-e and the p-type semiconductor layer 130-p is provided in an island shape in the pixel 100-px. Two adjacent pixels 100-px are separated by a groove portion in which the n-type semiconductor layer 130-n is exposed. Therefore, the upper surface of the n-type semiconductor layer 130-n, and each side surface of the light emitting layer 130-e and the p-type semiconductor layer 130-p is exposed in the groove portion. The side surface of the groove portion is inclined with respect to the substrate 110. For example, the inclination angle of the groove portion with respect to the substrate 110 is greater than or equal to 1 degree and less than or equal to 89 degrees, and preferably greater than or equal to 30 degrees and less than or equal to 60 degrees.

The electrode layer 140 is provided on the p-type semiconductor layer 130-p. The electrode layer 140 extends in the second direction and is provided commonly in a plurality of pixels 100-px arranged in the second direction. In the second direction, the electrode layer 140 provided in the groove portion faces the side surface of the light emitting layer 130-e.

The insulating layer 150 is provided in the groove portion. That is, the insulating layer 150 is provided so as to cover the upper surface of the n-type semiconductor layer 130-n and each side surface of the light emitting layer 130-e and the p-type semiconductor layer 130-p.

The reflective layer 160 is provided on the insulating layer 150. The reflective layer 160 extends in the second direction and is provided between two adjacent pixels 100-px in the first direction. Further, in the first direction, the reflective layer 160 provided in the groove portion faces the side surface of the light emitting layer 130-e. Therefore, the reflective layer 160 has the same inclination angle as the groove portion, and the inclination angle of the reflective layer 160 is greater than or equal to 1 degree and less than or equal to 89 degrees, and preferably greater than or equal to 30 degrees and less than or equal to 60 degrees, for example.

Each of the plurality of pixels 100-px includes the conductive alignment layer 120, the n-type semiconductor layer 130-n, the light emitting layer 130-e, the p-type semiconductor layer 130-p, and the electrode layer 140 as an LED. Here, one of the electrodes of the LED is the conductive alignment layer 120, and the other of the electrodes of the LED is the electrode layer 140. The conductive alignment layer 120 is provided commonly in the plurality of pixels 100-px arranged in a matrix while the electrode layer 140 is provided commonly in the plurality of pixels 100-px arranged in the second direction. Therefore, in the light emitting device 100, light emission from the plurality of pixels 100-px arranged in the second direction can be controlled as one unit.

Next, materials of each component are described.

The substrate 110 is a base material (support substrate) of the light emitting device 100. Although details are described later, each of the n-type semiconductor layer 130-n, the light emitting layer 130-e, and the p-type semiconductor layer 130-p is formed by sputtering in the light emitting device 100. Therefore, it is sufficient that the substrate 110 has a heat resistance of, for example, about 600 degrees, which is a relatively low temperature. For example, an amorphous glass substrate can be used as the substrate 110. Further, a resin substrate such as a polyimide substrate, an acrylic substrate, a siloxane substrate, or a fluororesin substrate can also be used as the substrate 110. Such an amorphous glass substrate or resin substrate is a substrate that can be made large in area.

Although not shown in the figures, the substrate 110 may be provided with a base layer. The base layer can prevent impurities from the substrate 110 or impurities from the outside (e.g., moisture, sodium (Na), etc.) from diffusing. For example, a silicon nitride (SiNₓ) film or the like can be used as the base layer. Further, for example, a laminated film of a silicon oxide (SiOₓ) film and a silicon nitride (SiNₓ) film can also be used as the base layer.

The conductive alignment layer 120 can improve the crystallinity of the gallium nitride (GaN) film deposited on the conductive alignment layer 120 by sputtering. Specifically, the conductive alignment layer 120 can perform control so as to align a c-axis of the gallium nitride film deposited on the conductive alignment layer 120 in the film thickness direction. In other words, the conductive alignment layer 120 can perform control such that the n-type semiconductor layer 130-n has a c-axis orientation. Although GaN having a hexagonal close-packed structure grows in the c-axis direction to minimize surface energy, the crystal growth in the c-axis direction is promoted by forming the gallium nitride film on the conductive alignment layer 120. A conductive material having a hexagonal close-packed structure, a face-centered cubic structure, or a structure equivalent thereto (for example, a wurtzite structure, a corundum structure, or a diamond structure) can be used as the conductive alignment layer 120. Here, the structure equivalent to the hexagonal close-packed structure or the face-centered cubic structure includes a crystal structure in which the c-axis is not 90 degrees with respect to the a-axis and the b-axis. The conductive alignment layer 120 using the conductive material having the hexagonal close-packed structure or the structure equivalent thereto has an orientation in the (0001) direction, that is, the c-axis direction with respect to the substrate 110 (hereinafter, referred to as a (0001) orientation of the hexagonal close-packed structure.). Further, the conductive alignment layer 120 using the conductive material having the face-centered cubic structure or the structure equivalent thereto has an orientation in the (111) direction with respect to the substrate 110 (hereinafter, referred to as a (111) orientation of the face-centered cubic structure.). When the conductive alignment layer 120 has the (0001) orientation of the hexagonal close-packed structure or the (111) orientation of a face-centered cubic structure, the crystal growth of the gallium nitride formed on the conductive alignment layer 120 is promoted. Therefore, the n-type semiconductor layer 130-n has a c-axis orientation with high crystallinity.

As described above, the crystallinity of the gallium nitride film on the conductive alignment layer 120 is affected by the surface condition of the conductive alignment layer 120. Therefore, it is preferable that the conductive alignment layer 120 has a smooth surface with little unevenness. For example, the arithmetic mean roughness (Ra) of the surface of the conductive alignment layer 120 is preferably less than 2.3 nm. Further, the root mean square roughness (Rq) of the surface of the conductive alignment layer 120 is preferably less than 2.9 nm. When the surface roughness of the conductive alignment layer 120 is under the above conditions, the n-type semiconductor layer 130-n has the c-axis orientation with higher crystallinity. In addition, the thickness of the conductive alignment layer 120 is greater than or equal to 5 nm and less than or equal to 50 nm, preferably greater than or equal to 15 nm and less than or equal to 30 nm.

The conductive alignment layer 120 not only functions as an n-type electrode of the LED but also functions to reflect the light emitted from the light emitting layer 130-e. Therefore, the conductive alignment layer 120 has both conductivity and reflectivity. For example, titanium (Ti), titanium nitride (TiNₓ), titanium oxide (TiOₓ), graphene, zinc oxide (ZnO), magnesium diboride (MgB₂), aluminum (Al), silver (Ag), calcium (Ca), nickel (Ni), copper (Cu), strontium (Sr), rhodium (Rh), palladium (Pd), cerium (Ce), ytterbium (Yb), iridium (Ir), platinum (Pt), gold (Au), lead (Pb), actinium (Ac), thorium (Th), BiLaTiO, SrFeO, BiFeO, BaFeO, ZnFeO, or PMnN-PZT can be used for the conductive alignment layer 120. In particular, it is preferable to use titanium for the conductive alignment layer 120.

The n-type semiconductor layer 130-n transports electrons and injects the electrons into the light emitting layer 130-e. For example, a gallium nitride film doped with silicon (Si) can be used as the n-type semiconductor layer 130-n.

The light emitting layer 130-e recombines the injected electrons and holes to emit light. The light emitting layer 130-e may have a multiple quantum well structure. For example, a laminated film in which indium gallium nitride (InGaN) films and gallium nitride films are alternately laminated can be used as the light emitting layer 130-e.

The p-type semiconductor layer 130-p transports holes and injects the holes into the light emitting layer 130-e. For example, a gallium nitride film doped with magnesium (Mg) can be used as the p-type semiconductor layer 130-p.

The electrode layer 140 functions as a p-type electrode of the LED. For example, a metal material such as palladium (Pd) or gold (Au) can be used for the electrode layer 140.

In the light emitting device 100, the electrode layer 140 may function as an n-type electrode of the LED. In this case, the light emitting device 100 has a structure in which the n-type semiconductor layer 130-n is in contact with the electrode layer 140. That is, the p-type semiconductor layer 130-p, the light emitting layer 130-e, and the n-type semiconductor layer 130-n are sequentially provided on the conductive alignment layer 120. In this case, a metal material such as silver (Ag) or indium (In), or a transparent conductive oxide such as indium tin oxide (ITO), indium zinc oxide (IZO), or zinc oxide (ZnO) can be used for the electrode layer 140, for example.

In the light emitting device 100, light emitted from the light emitting layer 130-e is extracted through the conductive alignment layer 120. Therefore, the conductive alignment layer 120 has light-transmitting or semi-light-transmitting properties. When a metal material is used for the conductive alignment layer 120, the conductive alignment layer 120 having semi-light-transmitting properties is formed by reducing the film thickness of the metal material. In addition, the conductive alignment layer 120 may have a laminate of a metal material and a transparent conductive oxide.

The insulating layer 150 separates (electrically insulates) the n-type semiconductor layer 130-n from the reflective layer 160. For example, an inorganic material such as silicon oxide or silicon nitride, or a laminate of these inorganic materials can be used for the insulating layer 150.

The reflective layer 160 reflects the light emitted from the side surface of the light emitting layer 130-e toward the lower surface direction of the light emitting device 100. For example, silver (Ag), titanium (Ti), molybdenum (Mo), tungsten (W), aluminum (Al), or an alloy thereof can be used for the reflective layer 160. The reflective layer 160 may also be conductive.

Although not shown in the figures, a protective film can be provided to cover the LED as necessary. A silicon nitride film can be used as the protective film. Further, for example, a laminated film of a silicon oxide film and a silicon nitride film can be used as the protective film.

In the light emitting device 100, the n-type semiconductor layer 130-n is in contact with the conductive alignment layer 120. Therefore, the crystallinity of the n-type semiconductor layer 130-n is improved. Further, the crystallinity of not only the n-type semiconductor layer 130-n but also the light emitting layer 130-e and the p-type semiconductor layer 130-p is improved. Therefore, in the light emitting device 100, the light emission intensity from the light emitting layer 130-e is increased.

Further, in the light emitting device 100, light emitted from the side surface of the light emitting layer 130-e is reflected by the reflective layer 160 in the first direction and by the electrode layer 140 in the second direction toward the lower surface direction of the light emitting device 100. Accordingly, in the light emitting device 100, the light extraction efficiency to the lower surface direction is increased, and the light emitting efficiency in the lower surface direction can be improved.

### First Modification of First Embodiment

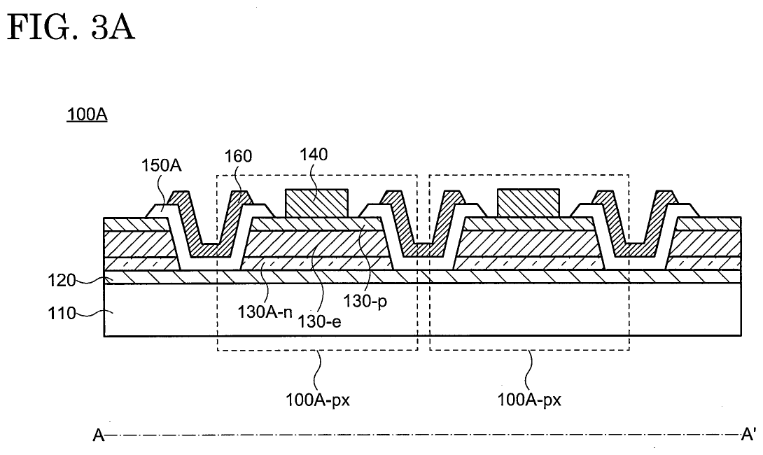

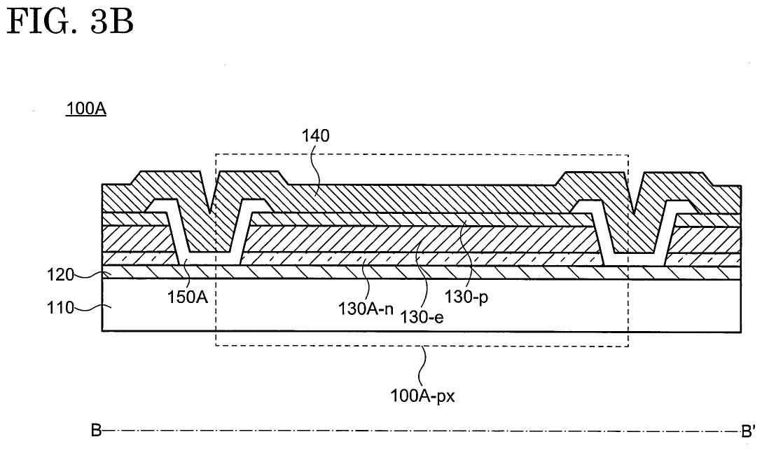

A light emitting device 100A, which is one of the modifications of the light emitting device 100 is described with reference to FIGS. 3A and 3B. In addition, when a configuration of the light emitting device 100A is similar to the configuration of the light emitting device 100, the description thereof may be omitted.

FIGS. 3A and 3B are cross-sectional views showing a configuration of the light emitting device 100A according to an embodiment of the present invention. Specifically, FIG. 3A is a cross-sectional view of a pixel 100A-px cut along the first direction, and FIG. 3B is a cross-sectional view of the pixel 100A-px cut along the second direction. As shown in FIGS. 3A and 3B, the light emitting device 100A includes the substrate 110, the conductive alignment layer 120, an n-type semiconductor layer 130A-n, the light emitting layer 130-e, the p-type semiconductor layer 130-p, the electrode layer 140, an insulating layer 150A, and the reflective layer 160.

The n-type semiconductor layer 130A-n is provided on the conductive alignment layer 120. The n-type semiconductor layer 130A-n is provided in an island shape in the pixel 100A-px. Two adjacent pixels 100A-px are separated by a groove portion in which the conductive alignment layer 120 is exposed. Therefore, in the groove portion, the side surfaces of the n-type semiconductor layer 130A-n, the light emitting layer 130-e, and the p-type semiconductor layer 130-p are exposed.

The insulating layer 150A is provided in the groove portion. That is, the insulating layer 150A is provided so as to cover the upper surface of the conductive alignment layer 120 and each side surface of the n-type semiconductor layer 130A-n, the light emitting layer 130-e, and the p-type semiconductor layer 130-p.

Each of the plurality of pixels 100A-px includes, the conductive alignment layer 120, the n-type semiconductor layer 130A-n, the light emitting layer 130-e, the p-type semiconductor layer 130-p, and the electrode layer 140 as an LED. Here, one of the electrodes of the LED is the conductive alignment layer 120, and the other of the electrodes of the LED is the electrode layer 140. The conductive alignment layer 120 is provided commonly to a plurality of pixels 100A-px arranged in a matrix while the electrode layer 140 is provided commonly in a plurality of pixels 100A-px arranged in the second direction. Therefore, in the light emitting device 100A, light emission of the plurality of pixels 100A-px arranged in the second direction can be controlled as one unit.

In the light emitting device 100A, the n-type semiconductor layer 130A-n is in contact with the conductive alignment layer 120. Therefore, the crystallinity of the n-type semiconductor layer 130A-n is improved. Further, the crystallinity of not only the n-type semiconductor layer 130A-n but also the light emitting layer 130-e and the p-type semiconductor layer 130-p is improved. Therefore, in the light emitting device 100A, the light emission intensity from the light emitting layer 130-e is increased.

Further, in the light emitting device 100A, light emitted from the side surface of the light emitting layer 130-e is reflected by the reflective layer 160 in the first direction and by the electrode layer 140 in the second direction toward the lower surface direction of the light emitting device 100A. Accordingly, in the light emitting device 100A, the light extraction efficiency to the lower surface direction is increased, and the light emitting efficiency in the lower surface direction can be improved.

### Second Modification of First Embodiment

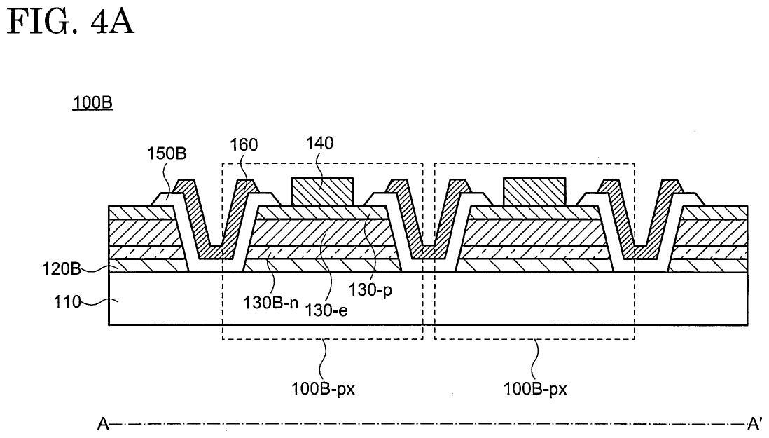

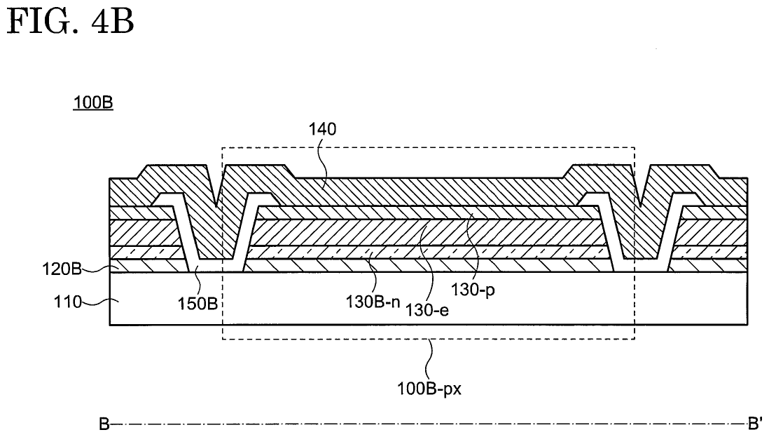

A light emitting device 100B, which is one of the modifications of the light emitting device 100 is described with reference to FIGS. 4A and 4B. In addition, when a configuration of the light emitting device 100B is similar to the configuration of the light emitting device 100, the description thereof may be omitted.

FIGS. 4A and 4B are cross-sectional views showing a configuration of the light emitting device 100B according to an embodiment of the present invention. Specifically, FIG. 4A is a cross-sectional view of a pixel 100B-px cut along the first direction, and FIG. 4B is a cross-sectional view of the pixel 100B-px cut along a second direction. As shown in FIGS. 4A and 4B, the light emitting device 100B includes the substrate 110, a conductive alignment layer 120B, an n-type semiconductor layer 130B-n, the light emitting layer 130-e, the p-type semiconductor layer 130-p, the electrode layer 140, an insulating layer 150B, and the reflective layer 160.

The conductive alignment layer 120B is provided on the substrate 110. The conductive alignment layer 120B is provided in an island shape in the pixel 100B-px.

The n-type semiconductor layer 130B-n is provided on the conductive alignment layer 120B. The n-type semiconductor layer 130B-n is provided in an island shape in the pixel 100B-px. Two adjacent pixels 100B-px are separated by the groove portion in which the substrate 110 is exposed. Therefore, the side surfaces of the conductive alignment layer 120B, the n-type semiconductor layer 130B-n, the light emitting layer 130-e, and the p-type semiconductor layer 130-p are exposed in the groove portion.

The insulating layer 150B is provided in the groove portion. That is, the insulating layer 150B is provided so as to cover the upper surface of the substrate 110 and each side surface of the conductive alignment layer 120B, the n-type semiconductor layer 130B-n, the light emitting layer 130-e, and the p-type semiconductor layer 130-p.

Each of the pixels 100B-px includes the conductive alignment layer 120B, the n-type semiconductor layer 130B-n, the light emitting layer 130-e, the p-type semiconductor layer 130-p, and the electrode layer 140 as an LED. Here, one of the electrodes of the LED is the conductive alignment layer 120B, and the other of the electrodes of the LED is the electrode layer 140. Although the conductive alignment layer 120B is provided in each of the pixels 100B-px, the electrode layer 140 is provided commonly in a plurality of pixels 100B-px arranged in the second direction. For example, a transistor that controls the LED is provided on the substrate 110 in the light emitting device 100B, and the conductive alignment layer 120B and the transistor are electrically connected to each other. Therefore, in the light emitting device 100B, light emission of each of the pixels 100B-px can be controlled. That is, it is possible to control the light emission of the pixels 100B-px by active driving in the light emitting device 100B.

In the light emitting device 100B, the n-type semiconductor layer 130B-n is in contact with the conductive alignment layer 120B. Therefore, the crystallinity of the n-type semiconductor layer 130B-n is improved. Further, the crystallinity of not only the n-type semiconductor layer 130B-n but also the light emitting layer 130-e and the p-type semiconductor layer 130-p is improved. Therefore, in the light emitting device 100B, the light emission intensity from the light emitting layer 130-e is increased.

Further, in the light emitting device 100B, light emitted from the side surface of the light emitting layer 130-e is reflected by the reflective layer 160 in the first direction and by the electrode layer 140 in the second direction toward the lower surface direction of the light emitting device 100B. Accordingly, in the light emitting device 100B, the light extraction efficiency to the lower surface direction is increased, and the light emitting efficiency in the lower surface direction can be improved.

### Third Modification of First Embodiment

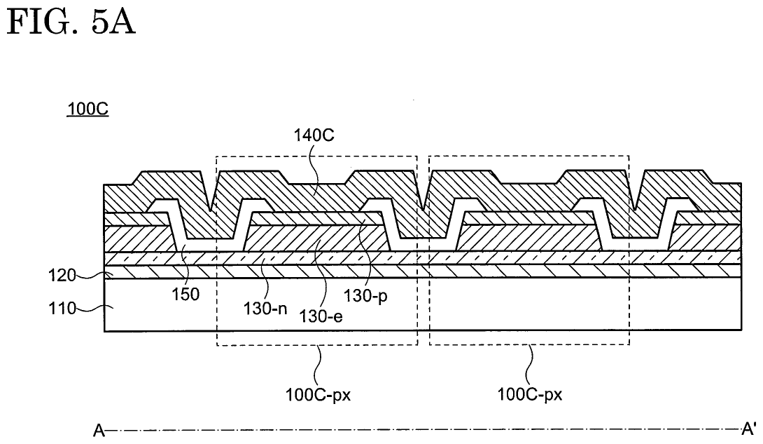

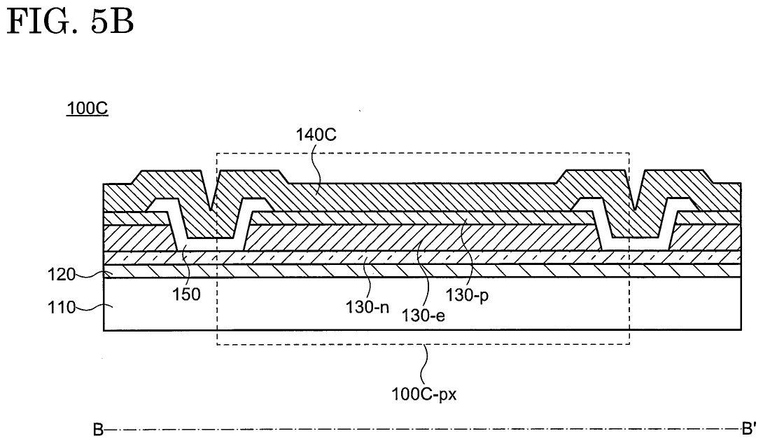

Alight emitting device 1000, which is one of the modifications of the light emitting device 100 is described with reference to FIGS. 5A and 5B. In addition, when a configuration of the light emitting device 1000 is similar to the configuration of the light emitting device 100, the description thereof may be omitted.

FIGS. 5A and 5B are cross-sectional views showing a configuration of the light emitting device 1000 according to an embodiment of the present invention. Specifically, FIG. 5A is a cross-sectional view of a pixel 1000-px cut along a first direction, and FIG. 5B is a cross-sectional view of a pixel 1000-px cut along a second direction. As shown in FIGS. 5A and 5B, the light emitting device 1000 includes the substrate 110, the conductive alignment layer 120, the n-type semiconductor layer 130-n, the light emitting layer 130-e, the p-type semiconductor layer 130-p, an electrode layer 140C, and the insulating layer 150.

The electrode layer 140C is provided on the p-type semiconductor layer 130-p and the insulating layer 150. The electrode layer 140C is provided commonly in a plurality of pixels 1000-px arranged in a matrix. In the first and second directions, the electrode layer 140C provided in the groove portion faces the side surface of the light emitting layer 130-e.

In addition, in the electrode layer 140C of the light emitting device 1000, the reflective layer is the same layer as the electrode layer, and is made of the same material.

Each of the pixels 1000-px includes the conductive alignment layer 120, the n-type semiconductor layer 130-n, the light emitting layer 130-e, the p-type semiconductor layer 130-p, and the electrode layer 140C as an LED. Here, one of the electrodes of the LED is the conductive alignment layer 120, and the other of the electrodes of the LED is the electrode layer 140C. Each of the conductive alignment layer 120 and the electrode layer 140C is provided commonly in the plurality of pixels 1000-px arranged in a matrix. Therefore, in the light emitting device 1000, light emission from the plurality of pixels 1000-px arranged in a matrix can be controlled as one unit.

In the light emitting device 1000, the n-type semiconductor layer 130-n is in contact with the conductive alignment layer 120. Therefore, the crystallinity of the n-type semiconductor layer 130-n is improved. Further, the crystallinity of not only the n-type semiconductor layer 130-n but also the light emitting layer 130-e and the p-type semiconductor layer 130-p is improved. Therefore, in the light emitting device 1000, the light emission intensity from the light emitting layer 130-e is increased.

Further, in the light emitting device 1000, light emitted from the side surface of the light emitting layer 130-e is reflected by the electrode layer 140 in the first and second directions toward the lower surface direction of the light emitting device 1000. Accordingly, in the light emitting device 1000, the light extraction efficiency to the lower surface direction is increased, and the light emitting efficiency in the lower surface direction can be improved.

### Fourth Modification of First Embodiment

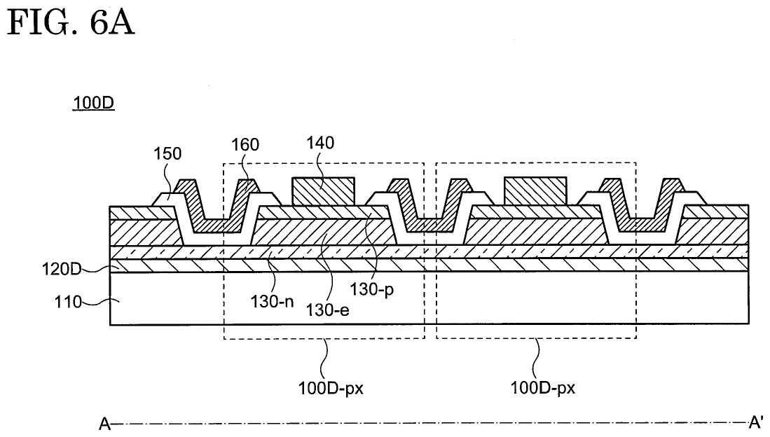

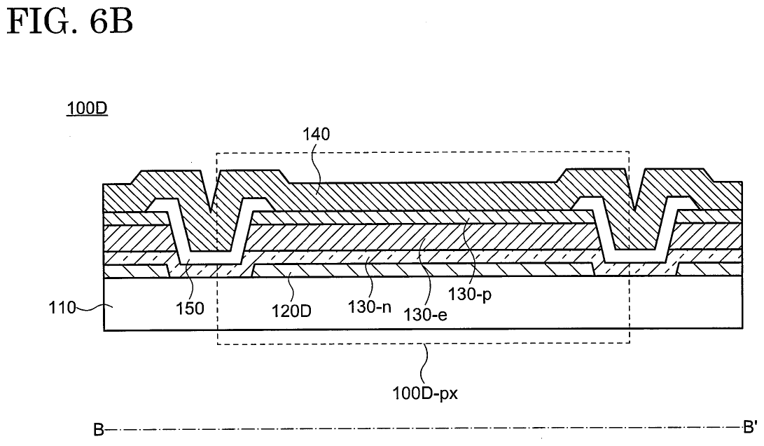

A light emitting device 100D, which is one of the modifications of the light emitting device 100 is described with reference to FIGS. 6A and 6B. In addition, when a configuration of the light emitting device 100D is similar to the configuration of the light emitting device 100, the description thereof may be omitted.

FIGS. 6A and 6B are cross-sectional views showing a configuration of the light emitting device 100D according to an embodiment of the present invention. Specifically, FIG. 6A is a cross-sectional view of a pixel 100D-px cut along the first direction, and FIG. 6B is a cross-sectional view of the pixel 100D-px cut along a second direction. As shown in FIGS. 6A and 6B, the light emitting device 100D includes the substrate 110, a conductive alignment layer 120D, the n-type semiconductor layer 130-n, the light emitting layer 130-e, the p-type semiconductor layer 130-p, the electrode layer 140, the insulating layer 150, and the reflective layer 160.

The conductive alignment layer 120D is provided on the substrate 110. The conductive alignment layer 120D extends in the first direction and is provided commonly in a plurality of pixels 100D-px arranged in the first direction.

Each of the plurality of pixels 100D-px includes the conductive alignment layer 120D, the n-type semiconductor layer 130-n, the light emitting layer 130-e, the p-type semiconductor layer 130-p, and the electrode layer 140 as an LED. Here, one of the electrodes of the LED is the conductive alignment layer 120D, and the other of the electrodes of the LED is the electrode layer 140. The conductive alignment layer 120D is provided commonly in the plurality of pixels 100D-px arranged in the first direction while the electrode layer 140 is provided commonly in a plurality of pixels 100D-px arranged in the second direction. Therefore, in the light emitting device 100D, light emission of the pixel 100D-px at the position where the conductive alignment layer 120D and the electrode layer 140 intersect each other. That is, it is possible to control the light emission of the pixel 100D-px by passive driving in the light emitting device 100D.

In the light emitting device 100D, the n-type semiconductor layer 130-n is in contact with the conductive alignment layer 120D. Therefore, the crystallinity of the n-type semiconductor layer 130-n is improved. Further, the crystallinity of not only the n-type semiconductor layer 130-n but also the light emitting layer 130-e and the p-type semiconductor layer 130-p is improved. Therefore, in the light emitting device 100D, the light emission intensity from the light emitting layer 130-e is increased.

Further, in the light emitting device 100D, light emitted from the side surface of the light emitting layer 130-e is reflected by the reflective layer 160 in the first direction and by the electrode layer 140 in the second direction toward the lower surface direction of the light emitting device 100D. Accordingly, in the light emitting device 100D, the light extraction efficiency to the lower surface direction is increased, and the light emitting efficiency in the lower surface direction can be improved.

### Second Embodiment

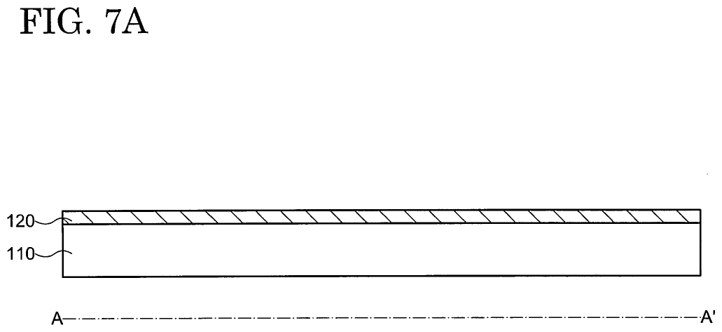

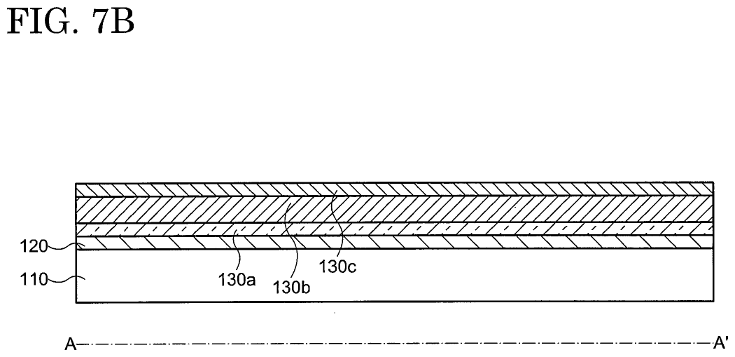

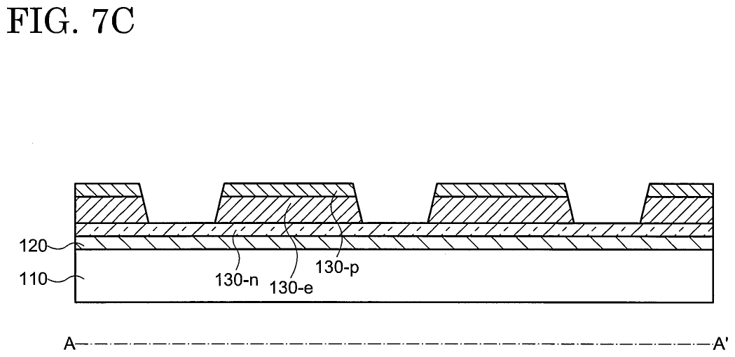

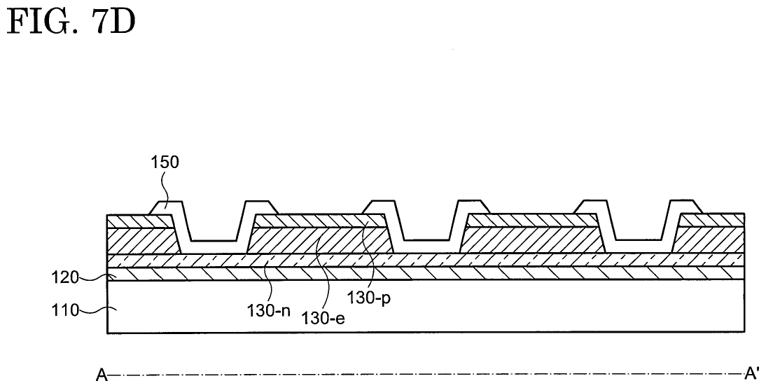

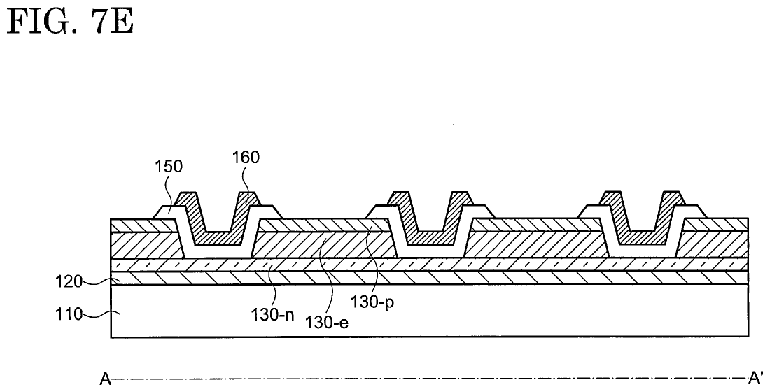

A method for manufacturing the light emitting device 100 according to an embodiment of the present invention is described with reference to FIGS. 7A to 7E. FIGS. 7A to 7E are schematic cross-sectional views showing a method for manufacturing the light emitting device 100 according to an embodiment of the present invention.

First, as shown in FIG. 7A, the conductive alignment layer 120 is formed on the substrate 110. The conductive alignment layer 120 can be formed by depositing a film using any method (apparatus) such as sputtering or CVD.

Next, as shown in FIG. 7B, an n-type semiconductor film 130a containing silicon-doped gallium nitride, a laminated film 130b in which indium gallium nitride films and gallium nitride films are alternately laminated, and a p-type semiconductor film 130c containing a magnesium-doped gallium nitride film are deposited. The n-type semiconductor film 130a, the laminated film 130b, and the p-type semiconductor film 130c are all deposited using sputtering.

Here, deposition of a gallium nitride film using sputtering is described as an example.

The substrate 110 on which the conductive alignment layer 120 is formed is placed to face a gallium nitride target in a vacuum chamber. It is preferable that the composition ratio of gallium nitride in the gallium nitride target is preferably greater than or equal to 0.7 and less or equal to 2 of gallium to nitrogen. Further, nitrogen can also be supplied to the vacuum chamber as a gas other than the sputtering gas (such as argon or krypton). In that case, it is preferable that the composition ratio of gallium nitride in the gallium nitride target is more gallium than nitrogen. For example, nitrogen can be supplied using a nitrogen radical source. The sputtering power supply source may be either a DC power supply source, an RF power supply source, or a pulsed DC power supply source.

The substrate 110 in the vacuum chamber may be heated. For example, the substrate 110 can be heated at a temperature higher than or equal to 100 degrees and lower than 600 degrees, preferably higher than or equal to 100 degrees and lower than or equal to 400 degrees. This substrate temperature can be applied even to an amorphous glass substrate with low heat resistance. Further, this substrate temperature is lower than the film formation temperature in MOCVD or HVPE.

After the vacuum chamber is sufficiently evacuated, the sputtering gas is supplied to the vacuum chamber. Further, a voltage is applied between the substrate 110 and the gallium nitride target at a predetermined pressure to generate plasma and the gallium nitride film is deposited.

Although the method for forming the gallium nitride film by sputtering is described above, the configuration or conditions of the sputtering process can be changed as appropriate. Further, an n-type nitride semiconductor film and a p-type nitride semiconductor film can be formed by using a silicon-doped gallium nitride target and a magnesium-doped target, respectively, instead of the gallium nitride target.

Next, as shown in FIG. 7C, the n-type semiconductor layer 130-n, the light emitting layer 130-e, and the p-type semiconductor layer 130-p are formed. The island-shaped light emitting layer 130-e and the p-type semiconductor layer 130-p are formed using photolithography. At this time, a part of the upper surface of the n-type semiconductor layer 130-n may be etched to form a recess. Further, the laminated film 130b and the p-type semiconductor film 130c may be patterned using a half-tone mask or a gray-tone mask in order to form the groove portion having an inclined side surface.

Next, as shown in FIG. 7D, the insulating layer 150 is formed in the groove portion. The insulating layer 150 is formed by depositing an inorganic material and patterning the inorganic material using photolithography.

Next, as shown in FIG. 7E, the reflective layer 160 is formed on the insulating layer 150. The reflective layer 160 is formed by depositing a metal material and patterning the metal material using photolithography.

Finally, the electrode layer 140 is formed on the p-type semiconductor layer 130-p, thereby the light emitting device 100 shown in FIGS. 2A and 2B is manufactured. The electrode layer 140 can be formed by deposition using any method (apparatus) such as sputtering or CVD.

In the method for manufacturing the light emitting device 100 of this embodiment, since it can be manufactured at a lower temperature than the conventional method, it is possible to use a large-area amorphous glass substrate as the substrate 110 and manufacture a plurality of light emitting devices 100 on the substrate 110. Therefore, the manufacturing cost of the light emitting device 100 can be suppressed.

### Third Embodiment

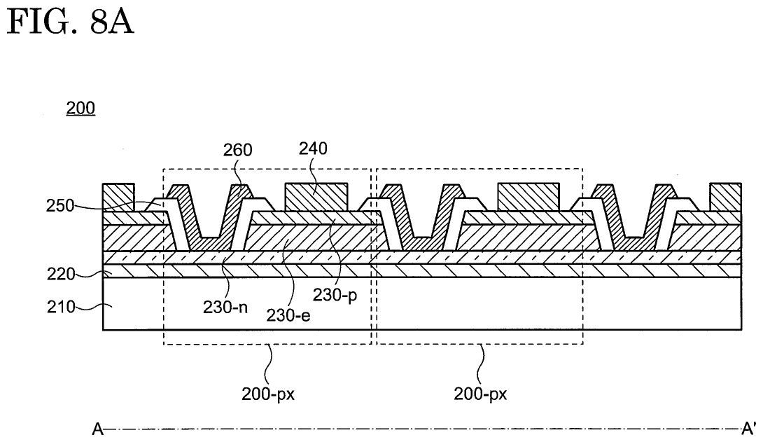

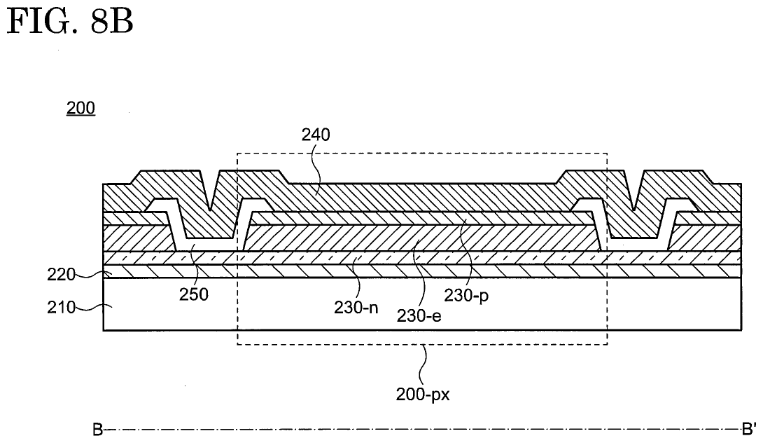

A configuration of a light emitting device 200 according to an embodiment of the present invention is described with reference to FIGS. 8A and 8B. In addition, when a configuration of the light emitting device 200 is similar to the configuration of the light emitting device 100, the description thereof may be omitted.

FIGS. 8A and 8B are schematic cross-sectional views showing a configuration of the light emitting device 200 according to an embodiment of the present invention. Specifically, FIG. 8A is a cross-sectional view of a pixel 200-px cut along the first direction, and FIG. 8B is a cross-sectional view of the pixel 200-px cut along the second direction. As shown in FIGS. 8A and 8B, the light emitting device 200 includes a substrate 210, an insulating alignment layer 220, an n-type semiconductor layer 230-n, a light emitting layer 230-e, a p-type semiconductor layer 230-p, an electrode layer 240, an insulating layer 250, and a reflective layer 260.

The insulating alignment layer 220 is provided on the substrate 210. The insulating alignment layer 220 is provided commonly in a plurality of pixels 200-px arranged in a matrix.

The n-type semiconductor layer 230-n, the light emitting layer 230-e, and the p-type semiconductor layer 230-p are sequentially provided on the insulating alignment layer 220. The n-type semiconductor layer 130-n is provided commonly in the plurality of pixels 200-px arranged in a matrix. Each of the light emitting layer 230-e and the p-type semiconductor layer 230-p is provided in an island shape in the pixel 200-px. Two adjacent laminated structures of the light emitting layer 230-e and the p-type semiconductor layer 230-p are separated by a groove portion in which the n-type semiconductor layer 230-n is exposed. Therefore, in the groove portion, the upper surface of the n-type semiconductor layer 230-n and each of the side surfaces of the light emitting layer 230-e and the p-type semiconductor layer 230-p are exposed. The side surface of the groove portion is inclined with respect to the substrate 210. For example, the inclination angle of the groove with respect to the substrate 210 is greater than or equal to 1 degree and less than or equal to 89 degrees, and preferably greater than or equal to 30 degrees and less than or equal to 60 degrees.

The electrode layer 240 is provided on the p-type semiconductor layer 230-p. The electrode layer 240 extends in the second direction and is provided commonly in a plurality of pixels 200-px arranged in the second direction. In the second direction, the electrode layer 240 provided in the groove portion faces the side surface of the light emitting layer 230-e.

In addition, although the electrode layer 240 is a p-type electrode, the electrode layer 240 may be an n-type electrode. In this case, the p-type semiconductor layer 230-p, the light emitting layer 230-e, and the n-type semiconductor layer 230-n are sequentially provided on the insulating alignment layer 220.

The insulating layer 250 is provided at least on the side surface of the groove portion. That is, the insulating layer 250 is provided so as to cover each side surface of the light emitting layer 230-e and the p-type semiconductor layer 230-p. Further, in the groove portion, the insulating layer 250 includes an opening portion through which the n-type semiconductor layer 230-n is exposed.

The reflective layer 260 is provided on the n-type semiconductor layer 230-n and the insulating layer 250. That is, the reflective layer 260 is in contact with the n-type semiconductor layer 230-n through the opening portion of the insulating layer 250. The reflective layer 260 extends in the second direction and is provided commonly in the plurality of pixels 200-px arranged in the second direction. Further, the reflective layer 260 provided in the groove portion faces the side surface of the light emitting layer 230-e in the first direction. Therefore, the reflective layer 260 has the same inclination angle as the groove portion, and the inclination angle of the reflective layer 260 is greater than or equal to 1 degree and less than or equal to 89 degrees, and preferably greater than or equal to 30 degrees and less than or equal to 60 degrees, for example.

Each of the plurality of pixels 200-px includes the reflective layer 260, the n-type semiconductor layer 230-n, the light emitting layer 230-e, the p-type semiconductor layer 230-p, and the electrode layer 240 as an LED. Here, one of the electrodes of the LED is the reflective layer 260, and the other of the electrodes of the LED is the electrode layer 240. The reflective layer 260 and the electrode layer 240 are provided commonly in the plurality of pixels 200-px arranged in a matrix in the second direction. Therefore, in the light emitting device 200, light emission from the plurality of pixels 200-px arranged in the second direction can be controlled as one unit.

Next, materials of each component are described.

The substrate 210, the n-type semiconductor layer 230-n, the light emitting layer 230-e, the p-type semiconductor layer 230-p, the electrode layer 240, the insulating layer 250, and the reflective layer 260 are the same material as the substrate 110, the n-type semiconductor layer 130-n, the light emitting layer 130-e, the p-type semiconductor layer 130-p, the electrode layer 140, the insulating layer 150, and the reflective layer 160, respectively.

The insulating alignment layer 220 has insulating properties and can improve the crystallinity of the n-type semiconductor layer 230-n deposited on the insulating alignment layer 220. For example, aluminum nitride (AlN), aluminum oxide (Al₂O₃), lithium niobate (LiNbO), BiLaTiO, SrFeO, SrFeO, BiFeO, BaFeO, ZnFeO, PMnN-PZT, or biological apatite (BAp) can be used as the insulating alignment layer 220. In particular, it is preferable to use aluminum nitride (AlN) for the insulating alignment layer 220.

In the light emitting device 200, the n-type semiconductor layer 230-n is in contact with the insulating alignment layer 220. Therefore, the crystallinity of the n-type semiconductor layer 230-n is improved. Further, the crystallinity of not only the n-type semiconductor layer 230-n but also the light emitting layer 230-e and the p-type semiconductor layer 230-p is improved. Therefore, in the light emitting device 200, the light emission intensity from the light emitting layer 230-e is increased.

Further, in the light emitting device 200, light emitted from the side surface of the light emitting layer 230-e is reflected by the reflective layer 260 in the first direction and by the electrode layer 240 in the second direction toward the lower surface direction of the light emitting device 200. Accordingly, in the light emitting device 200, the light extraction efficiency to the lower surface direction is increased, and the light emitting efficiency in the lower surface direction can be improved.

### First Modification of Third Embodiment

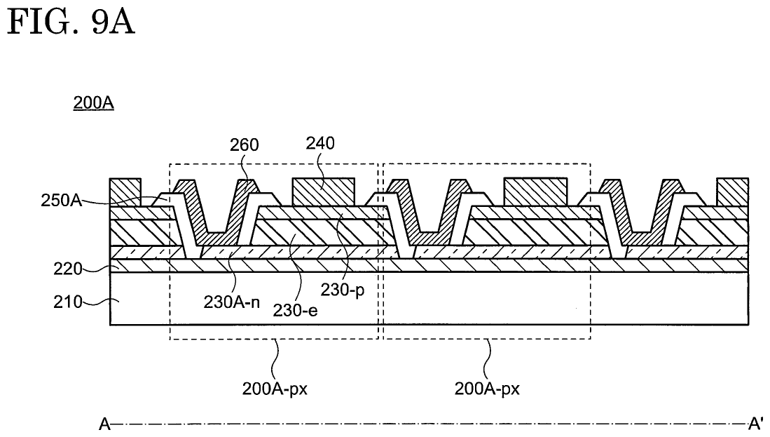

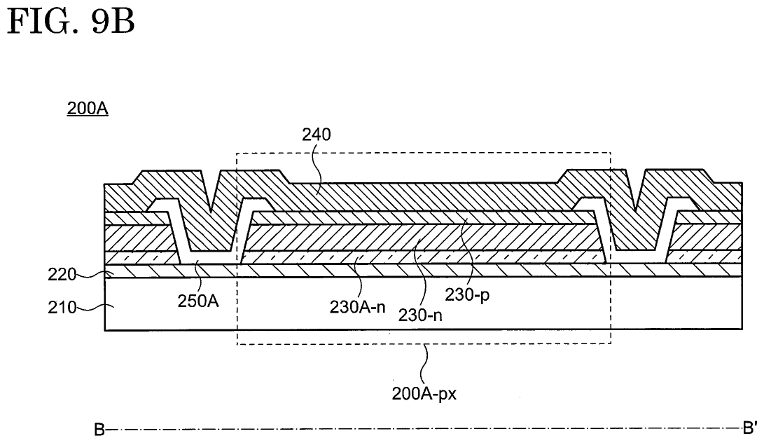

A light emitting device 200A, which is one of the modifications of the light emitting device 200 is described with reference to FIGS. 9A and 9B. In addition, when a configuration of the light emitting device 200A is similar to the configuration of the light emitting device 200, the description thereof may be omitted.

FIGS. 9A and 9B are cross-sectional views showing a configuration of the light emitting device 200A according to an embodiment of the present invention. Specifically, FIG. 9A is a cross-sectional view of a pixel 200A-px cut along the first direction, and FIG. 9B is a cross-sectional view of the pixel 200A-px cut along the second direction. As shown in FIGS. 9A and 9B, the light emitting device 200A includes the substrate 210, the insulating alignment layer 220, an n-type semiconductor layer 230A-n, the light emitting layer 230-e, the p-type semiconductor layer 230-p, the electrode layer 240, an insulating layer 250A, and the reflective layer 260.

The n-type semiconductor layer 230A-n is provided on the insulating alignment layer 220. The n-type semiconductor layer 230A-n is provided in an island shape in the pixel 200A-px.

The insulating layer 250A is provided at least on the side surface of the groove portion. That is, the insulating layer 250A is provided so as to cover each side surface of the light emitting layer 230-e and the p-type semiconductor layer 230-p. Further, in the groove portion, the insulating layer 250A includes an opening portion through which the n-type semiconductor layer 230A-n is exposed. In addition, the insulating layer 250A is also provided between two adjacent n-type semiconductor layers 230A-n. That is, the two adjacent n-type semiconductor layers 230A-n are separated by the insulating layer 250A.

Each of the plurality of pixels 200A-px includes the reflective layer 260, the n-type semiconductor layer 230A-n, the light emitting layer 230-e, the p-type semiconductor layer 230-p, and the electrode layer 240 as an LED. Here, one of the electrodes of the LED is the reflective layer 260, and the other of the electrodes of the LED is the electrode layer 240. The reflective layer 260 and the electrode layer 240 are provided commonly in a plurality of pixels 200A-px arranged in the second direction. Therefore, in the light emitting device 200A, light emission of the plurality of pixels 200A-px arranged in the second direction can be controlled as one unit.

In the light emitting device 200A, the n-type semiconductor layer 230A-n is in contact with the insulating alignment layer 220. Therefore, the crystallinity of the n-type semiconductor layer 230A-n is improved. Further, the crystallinity of not only the n-type semiconductor layer 230A-n but also the light emitting layer 230-e and the p-type semiconductor layer 230-p is improved. Therefore, in the light emitting device 200A, the light emission intensity from the light emitting layer 230-e is increased.

Further, in the light emitting device 200A, light emitted from the side surface of the light emitting layer 230-e is reflected by the reflective layer 260 in the first direction and by the electrode layer 240 in the second direction toward the lower surface direction of the light emitting device 200A. Accordingly, in the light emitting device 200A, the light extraction efficiency to the lower surface direction is increased, and the light emitting efficiency in the lower surface direction can be improved.

### Second Modification of Third Embodiment

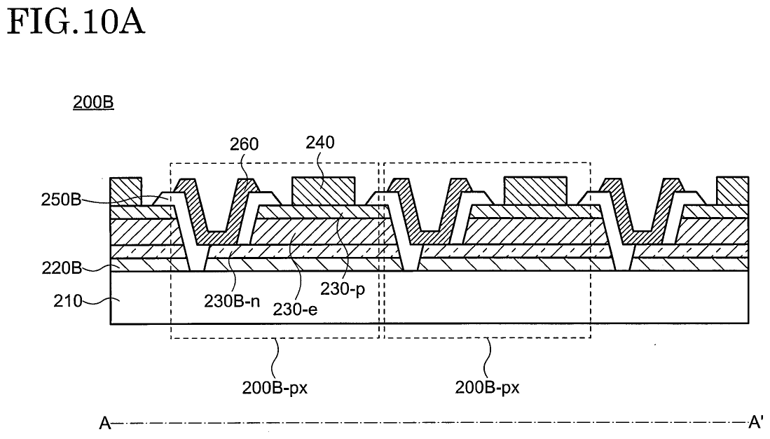

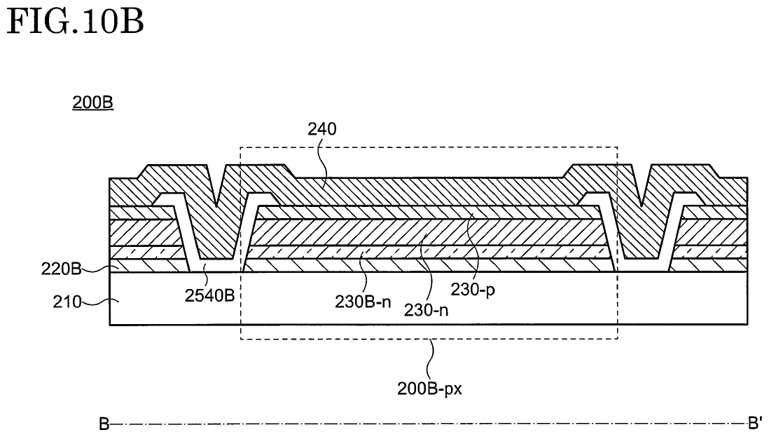

A light emitting device 200B, which is one of the modifications of the light emitting device 200 is described with reference to FIGS. 10A and 10B. In addition, when a configuration of the light emitting device 200B is similar to the configuration of the light emitting device 200, the description thereof may be omitted.

FIGS. 10A and 10B are cross-sectional views showing a configuration of the light emitting device 200B according to an embodiment of the present invention. Specifically, FIG. 10A is a cross-sectional view of a pixel 200B-px cut along the first direction, and FIG. 10B is a cross-sectional view of the pixel 200B-px cut along the second direction. As shown in FIGS. 10A and 10B, the light emitting device 200B includes the substrate 210, an insulating alignment layer 220B, an n-type semiconductor layer 230B-n, the light emitting layer 230-e, the p-type semiconductor layer 230-p, the electrode layer 240, an insulating layer 250B, and the reflective layer 260.

The insulating alignment layer 220B is provided on the substrate 210. The insulating alignment layer 220B is provided in an island shape in the pixel 200B-px.

The n-type semiconductor layer 230B-n is provided on the insulating alignment layer 220B. The n-type semiconductor layer 230B-n is provided in an island shape in the pixel 200B-px.

The insulating layer 250B is provided at least on the side surface of the groove portion. That is, the insulating layer 250B is provided so as to cover each side surface of the light emitting layer 230-e and the p-type semiconductor layer 230-p. Further, in the groove, the insulating layer 250B includes an opening portion in which the n-type semiconductor layer 230B-n is exposed. In addition, the insulating layer 250B is also provided between two adjacent laminated structures of the insulating alignment layer 220B and the n-type semiconductor layer 230B-n. That is, the two laminates of the insulating alignment layer 220B and the n-type semiconductor layer 230B-n are separated by the insulating layer 250B.

Each of the plurality of pixels 200B-px includes the reflective layer 260, the n-type semiconductor layer 230B-n, the light emitting layer 230-e, the p-type semiconductor layer 230-p, and the electrode layer 240 as an LED. Here, one of the electrodes of the LED is the reflective layer 260, and the other of the electrodes of the LED is the electrode layer 240. The reflective layer 260 and the electrode layer 240 are provided commonly in a plurality of pixels 200B-px arranged in the second direction. Therefore, in the light emitting device 200B, light emission of the plurality of pixels 200B-px arranged in the second direction can be controlled as one unit.

In the light emitting device 200B, the n-type semiconductor layer 230B-n is in contact with the insulating alignment layer 220B. Therefore, the crystallinity of the n-type semiconductor layer 230B-n is improved. Further, the crystallinity of not only the n-type semiconductor layer 230B-n but also the light emitting layer 230-e and the p-type semiconductor layer 230-p is improved. Therefore, in the light emitting device 200B, the light emission intensity from the light emitting layer 230-e is increased.

Further, in the light emitting device 200B, light emitted from the side surface of the light emitting layer 230-e is reflected by the reflective layer 260 in the first direction and by the electrode layer 240 in the second direction toward the lower surface direction of the light emitting device 200B. Accordingly, in the light emitting device 200B, the light extraction efficiency to the lower surface direction is increased, and the light emitting efficiency in the lower surface direction can be improved.

### Fourth Embodiment

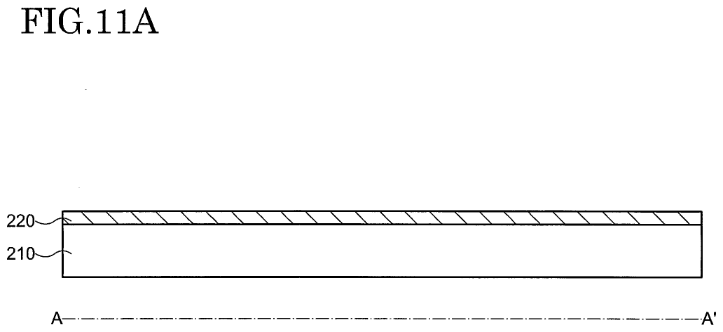

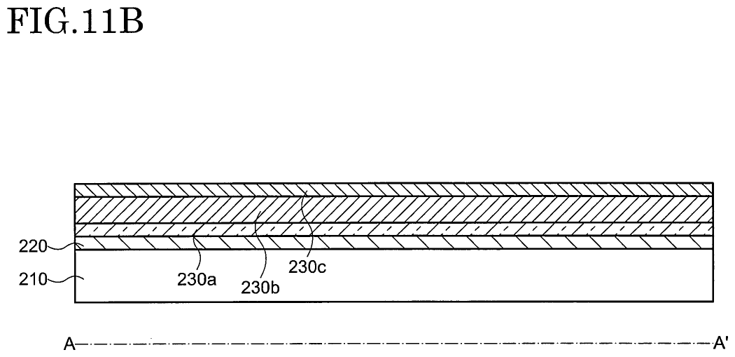

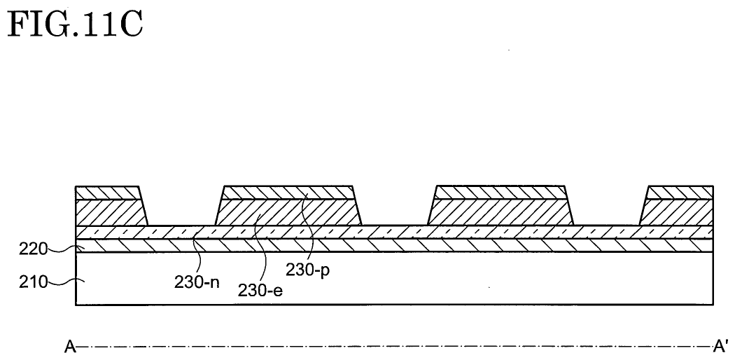

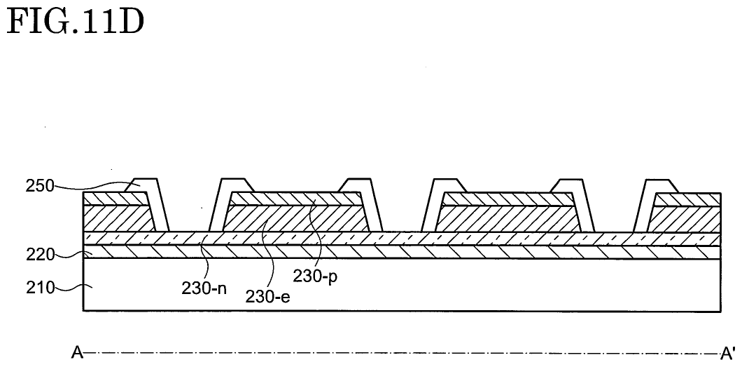

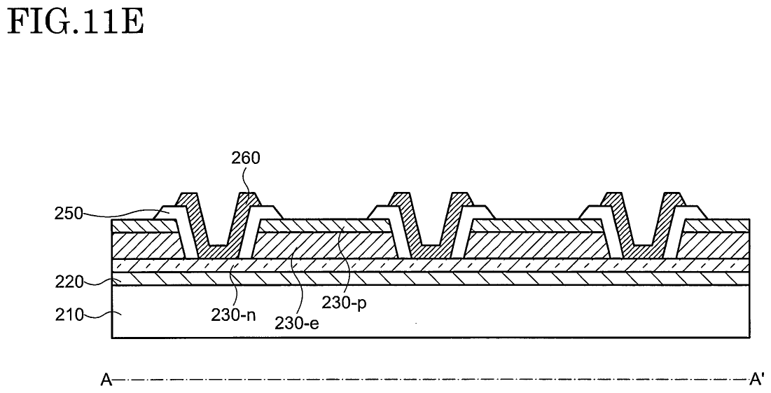

A method for manufacturing the light emitting device 200 according to an embodiment of the present invention is described with reference to FIGS. 11A to 11E. FIGS. 11A to 11E are schematic cross-sectional views showing a method for manufacturing the light emitting device 200 according to an embodiment of the present invention.

First, as shown in FIG. 11A, the insulating alignment layer 220 is formed on the substrate 210. The insulating alignment layer 220 can be formed by depositing a film using any method (apparatus) such as sputtering or CVD.

Next, as shown in FIG. 11B, an n-type semiconductor film 230a containing silicon-doped gallium nitride, a laminated film 230b in which indium gallium nitride films and gallium nitride films are alternately laminated, and a p-type semiconductor film 230c containing a magnesium-doped gallium nitride film are deposited. The n-type semiconductor film 230a, the laminated film 230b, and the p-type semiconductor film 230c are all deposited using sputtering.

Next, as shown in FIG. 11C, the n-type semiconductor layer 230-n, the light emitting layer 230-e, and the p-type semiconductor layer 230-p are formed. The island-shaped light emitting layer 230-e and the p-type semiconductor layer 230-p are formed using photolithography. At this time, a part of the upper surface of the n-type semiconductor layer 230-n may be etched to form a recess. Further, the laminated film 230b and the p-type semiconductor film 230c may be patterned using a half-tone mask or a gray-tone mask in order to form the groove portion having an inclined side surface.

Next, as shown in FIG. 11D, the insulating layer 250 including the opening portion in which the n-type semiconductor layer 230-n is exposed is formed in the groove portion. The insulating layer 250 is formed by depositing an inorganic material and patterning the inorganic material by photolithography.

Next, as shown in FIG. 11E, the reflective layer 260 is formed on the n-type semiconductor layer 230-n and the insulating layer 250. The reflective layer 260 is formed by depositing a metal material and patterning the metal material using photolithography.

Finally, the electrode layer 240 is formed on the p-type semiconductor layer 230-p, thereby the light emitting device 200 shown in FIGS. 8A and 8B is manufactured. The electrode layer 240 can be formed by deposition using any method (apparatus) such as sputtering or CVD.

In the method for manufacturing the light emitting device 200 of this embodiment, since it can be manufactured at a lower temperature than the conventional method, it is possible to use a large-area amorphous glass substrate as the substrate 210 and manufacture a plurality of light emitting devices 200 on the substrate 210. Therefore, the manufacturing cost of the light emitting device 200 can be suppressed.

### Fifth Embodiment

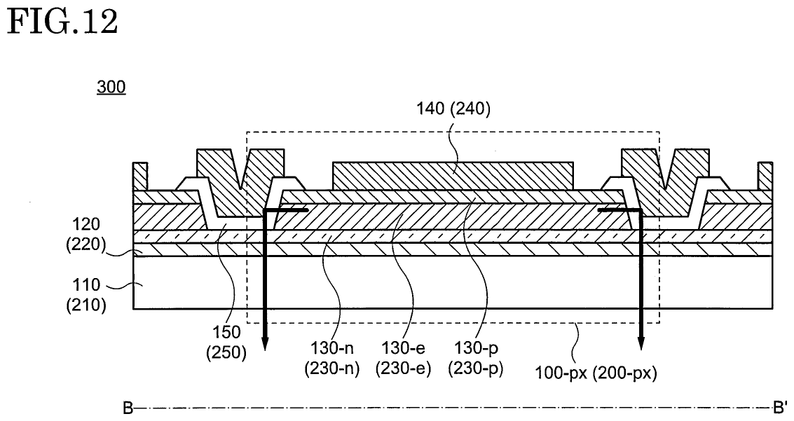

A light emitting device 300 according to an embodiment of the present invention is described with reference to FIG. 12.

FIG. 12 is a schematic cross-sectional view showing a configuration of the light emitting device 300 according to an embodiment of the present invention. Although the light emitting device 300 shown in FIG. 12 has a different configuration from the electrode layer 140 as shown in FIG. 2B and the electrode layer 240 as shown in FIG. 8B, the light emitting device 300 has a common configuration in FIG. 2B or FIG. 8B. In addition, the common configuration shown in FIG. 2B or FIG. 8B is omitted in the following description.

Unlike FIG. 2B or FIG. 8B, an electrode layer 140 (240) of the light emitting device 300 does not extend across adjacent pixels in the second direction. The electrode layer 140 (240) is formed in an island shape for each pixel 100-PX (200-PX). A groove portion is formed between adjacent pixels in the same manner as in the configuration shown in FIG. 2B or FIG. 8B, and a reflective layer is formed in the groove portion to be spaced apart from the electrode layer 140 (240). For example, the reflective layer of the light emitting device 300 is formed in the same layer as the electrode layer 140 (240) and spaced apart from the electrode layer 140 (240) by patterning the electrode layer 140 (240) shown in FIG. 2B or FIG. 8B.

In the light emitting device 300, an electrode layer 140 (240) is formed for each pixel 100-PX (200-PX). The electrode layer 140 (240) for each pixel 100-PX (200-PX) is electrically connected to, for example, an electrode provided on a substrate having a transistor, thereby enabling control of each pixel 100-PX (200-PX) by active driving.

### Sixth Embodiment

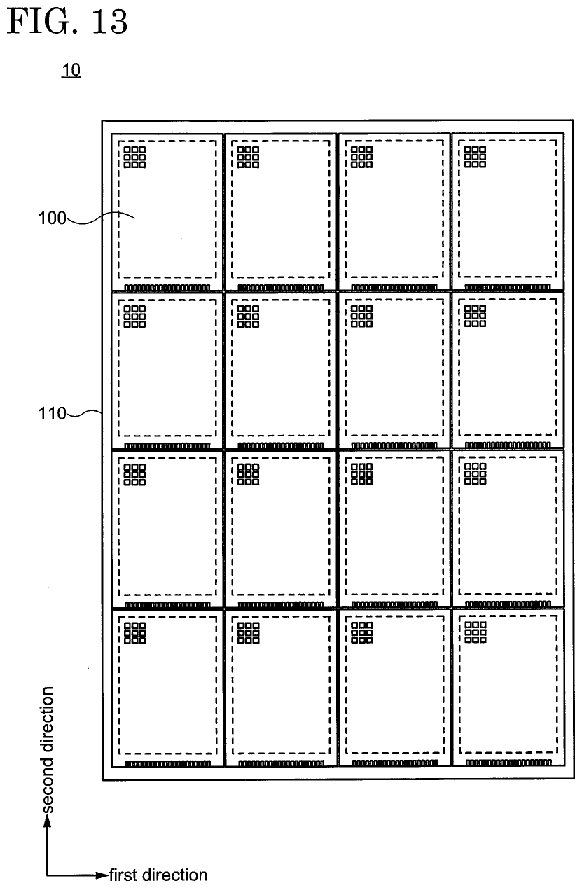

A light emitting device forming substrate 10 according to an embodiment of the present invention is described with reference to FIG. 13.

FIG. 13 is a schematic diagram showing a configuration of the light emitting device formation substrate 10 according to an embodiment of the present invention. The light emitting device formation substrate 10 includes the plurality of light emitting devices 100. That is, in the light emitting device formation substrate 10, the plurality of light emitting devices 100 are manufactured using one substrate 110. The substrate 110 is a so-called large-area substrate. In the light emitting device formation substrate 10, the plurality of light emitting devices 100 can be manufactured at once using a large-area substrate, so that the manufacturing cost of the light emitting devices 100 can be suppressed.

Each of the embodiments described above as an embodiment of the present invention can be appropriately combined and implemented as long as they do not contradict each other. Additions, deletions, or design changes of constituent elements, or additions, omissions, or changes to conditions of steps as appropriate based on the respective embodiments are also included within the scope of the present invention as long as the gist of the present invention is provided.

Other effects which differ from those brought about by each of the embodiments described above, but which are apparent from the description herein or which can be readily predicted by those skilled in the art, are naturally understood to be brought about by the present invention.

What is claimed is:

1. A light emitting device comprising:
a plurality of pixels arranged in a matrix in a first direction and in a second direction orthogonal to the first direction, over a substrate,
wherein each of the plurality of pixels arranged in a matrix comprises:
a conductive alignment layer over the substrate,
a semiconductor layer comprising gallium nitride over the conductive alignment layer,
a light emitting layer in an island shape over the semiconductor layer, and
an electrode layer over the light emitting layer,
a side surface of the light emitting layer is covered with an insulating layer, and
a reflective layer facing the side surface of the light emitting layer is provided over the insulating layer.

2. The light emitting device according to claim 1, wherein the reflective layer is inclined with an inclination angle greater than or equal to 30 degrees and less than or equal to 60 degrees with respect to the substrate.

3. The light emitting device according to claim 1, wherein the semiconductor layer is provided commonly in the plurality of pixels arranged in a matrix.

4. The light emitting device according to claim 1,
wherein the semiconductor layer is provided in an island shape, and
a side surface of the semiconductor layer is covered with the insulating layer.

5. The light emitting device according to claim 1, wherein the reflective layer is a same layer as the electrode layer.

6. The light emitting device according to claim 1,
wherein the conductive alignment layer extends in the first direction and is provided commonly in a plurality of pixels arranged in the first direction, and
the electrode layer extends in the second direction and is provided commonly in a plurality of pixels arranged in the second direction.

7. The light emitting device according to claim 1,
wherein the conductive alignment layer is provided in an island shape, and
a side surface of the conductive alignment layer is covered with the insulating layer.

8. The light emitting device according to claim 1, wherein the conductive alignment layer comprises at least one of titanium and silver.

9. The light emitting device according to claim 1, wherein the substrate is amorphous.

10. The light emitting device according to claim 1, wherein the substrate is polycrystalline.

11. A light emitting device comprising:
a plurality of pixels arranged in a matrix in a first direction and in a second direction orthogonal to the first direction, over a substrate,
wherein each of the plurality of pixels arranged in a matrix comprises:
an insulating alignment layer over the substrate,
a semiconductor layer comprising gallium nitride over the insulating alignment layer,
a light emitting layer in an island shape over the semiconductor layer,
an electrode layer over the light emitting layer,
an insulating layer covering a side surface of the light emitting layer, and
a reflective layer facing the side surface of the light emitting layer, over the insulating layer, and
the reflective layer is in contact with the semiconductive layer.

12. The light emitting device according to claim 11, wherein the reflective layer is inclined with an inclination angle greater than or equal to 30 degrees and less than or equal to 60 degrees with respect to the substrate.

13. The light emitting device according to claim 11, wherein the semiconductor layer is provided commonly in the plurality of pixels arranged in a matrix.

14. The light emitting device according to claim 11,
wherein the semiconductor layer is provided in an island shape, and
a side surface of the semiconductor layer is covered with the insulating layer.

15. The light emitting device according to claim 11, wherein each of the electrode layer and the reflective layer extends in the second direction and is provided commonly in a plurality of pixels arranged in the second direction.

16. The light emitting device according to claim 11,
wherein the insulating alignment layer is provided in an island shape, and
a side surface of the insulating alignment layer is covered with the insulating layer.

17. The light emitting device according to claim 1, wherein the insulating alignment layer comprises at least one of aluminum oxide and aluminum nitride.

18. The light emitting device according to claim 11, wherein the substrate is amorphous.

19. The light emitting device according to claim 11, wherein the substrate is polycrystalline.
